(19) United States
(12) Patent Application Publication
(10) Pub. No.: US 2025/0246469 A1
(43) Pub. Date: Jul. 31, 2025

(54) SUBSTRATE HANDLING SYSTEM

(71) Applicant: ASM IP Holding B. V., Almere (NL)

(72) Inventors: Frans Wiegers, Vleuten (NL); Jeroen de Jonge, Almere (NL); Martim Pereira Gonçalves, Amsterdam (NL); Michiel Barend Kalmeijer, Hilversum (NL)

(21) Appl. No.: 19/039,594

(22) Filed: Jan. 28, 2025

Related U.S. Application Data
(60) Provisional application No. 63/626,300, filed on Jan. 29, 2024.

(51) Int. Cl. H01L 21/68; G01S 17/894; H01L 21/67; H01L 21/677

(52) U.S. Cl. CPC H01L 21/681; G01S 17/894; H01L 21/67259; H01L 21/67265; H01L 21/67288; H01L 21/67294; H01L 21/67772; H01L 21/67778; H01L 21/67766

(57) ABSTRACT

A substrate handling system is disclosed. The substrate handling system comprises a substrate handling robot for transferring a substrate among a plurality of substrate stations; and a lidar imaging system comprising a lidar image acquisition module located on the substrate handling robot, the lidar imaging system being configured to acquire at least one 3D image of a substrate and/or a substrate station, and to determine one or more properties of the substrate and/or the substrate station, based on the at least one 3D image.

### CROSS-REFERENCE TO RELATED APPLICATION(S)

This application claims the benefit of U.S. Provisional Application 63/626,300 filed on Jan. 29, 2024, the entire contents of which are incorporated herein by reference.

### FIELD OF INVENTION

The present application relates generally to substrate processing and, more particularly, to methods and apparatuses for handling substrates.

### BACKGROUND OF THE DISCLOSURE

An apparatus for processing semiconductor substrates, such as silicon wafers, typically includes a processing chamber in which the substrates are processed, a substrate handling chamber through which the substrates are moved before and after processing in the processing chamber, and one or more input/output chambers that store substrates before and after the substrates are moved through the handling chamber. A substrate handling robot is located within the handling chamber and is configured to transfer substrates to and from a plurality of stations. Such stations may be within the handling chamber, the input/output chambers, the processing chamber, or other chambers. A typical station within the processing chamber is a substrate holder, such as a wafer boat or a susceptor, which supports a substrate during processing. A station within the input/output chamber may comprise a cassette that holds a plurality of substrates. The input/output chambers may be loading chambers or load ports that contain substrate cassettes that are accessible by the transfer robot. The input/output chambers can also be load-lock chambers in which substrates can be atmospherically isolated and purged of particulates before being moved into the handling chamber and eventually into the processing chamber. Other stations, which can be inside separate chambers or even within the substrate handling chamber, may include pre-processing stations (such as a wafer pre-cleaning station) and/or post-processing stations (such as a cooling station).

The substrate handling robot typically includes an actuator, one or more interlinked arms, and an end effector attached to the arms. The actuator is configured to move the arms and the end effector. The end effector is adapted to pick up a substrate from a station, hold the substrate as the robot moves the end effector and the substrate to another station, and place the substrate at another station. A variety of different types of end effectors exist, some of which may be multiple end effectors e.g. dual end effectors capable of supporting more than one substrate at the same time.

In some tools, the apparatus includes a plurality of processing chambers each typically adjacent to the substrate handling chamber. The processing chambers are capable of processing substrates simultaneously, which increases the overall substrate throughput of the apparatus. The handling chamber may include more than one substrate handling robot for improved substrate handling capability.

The substrates processed by the apparatus may be defective before or after processing, for example due to damage during storage or loading of the substrates into the apparatus, damage during processing or during transfer by the substrate handling robot. Processing of damaged substrates is not desired as this increases the running cost of the apparatus.

The correct placement of substrates in a susceptor or boat carrier or other structure for supporting substrate(s) during processing is an important factor in obtaining high quality processed substrates. Misalignment or cross-slotting of substrates can lead to incorrect or substandard processing of substrates.

### SUMMARY OF THE DISCLOSURE

According to a first embodiment of the present invention, there is provided a substrate handling system comprising a substrate handling robot for transferring a substrate among a plurality of substrate stations; and a lidar imaging system comprising a lidar image acquisition module located on the substrate handling robot, the lidar imaging system being configured to acquire at least one 3D image of a substrate and/or a substrate station, and to determine one or more properties of the substrate and/or the substrate station, based on the at least one 3D image.

It is an advantage of embodiments of the present invention that, by acquiring and analyzing one or more three-dimensional images, properties of a substrate and/or substrate station can be determined which are difficult or impossible to obtain from a two dimensional image. it is an advantage of embodiments of the present invention that, by locating the lidar image acquisition module on the substrate handling robot, the position of the lidar image acquisition module can be controlled, which allows images to be acquired from various relative positions between the lidar image acquisition module and a substrate and/or substrate station.

The lidar imaging system may be configured to acquire at least one 3D image while the substrate handling robot is stationary.

The lidar imaging system may be configured to acquire at least one 3D image while the substrate handling robot is in motion.

The lidar imaging system may be configured to acquire a first 3D image of the substrate and/or substrate station from a first relative position and a second 3D image of the same substrate and/or substrate station from a second relative position different to the first relative position, and to determine one or more properties of the same substrate and/or substrate station based on the first and second 3D images.

The lidar imaging system may be configured to combine two or more 3D images of the same substrate and/or substrate station to create a combined image and to determine one or more properties of the substrate and/or substrate station based on the combined image. This can allow a 3D image of an object to be built up from more than one angle, providing more information than a single image from one angle.

The substrate handling system may comprise a substrate handling robot control module configured to receive at least one property determined based on at least one 3D image from the lidar imaging system, and to adapt a behavior of the substrate handling robot based on the at least one property.

At least one 3D image may include at least part of a substrate and the property may include a warpage of the substrate.

At least one 3D image may include at least part of a substrate and the property may include a parameter indicative of substrate damage.

At least one 3D image may include at least part of a substrate and the property may include a substrate identification code.

At least one 3D image may include at least part of a substrate and the property may include a position of a center of the substrate.

The substrate station may be a boat. At least one 3D image may include at least part of a boat and the property may include a parameter indicative of location of substrate(s) in the boat.

At least one 3D image may include at least part of a boat and the property may include a parameter indicative of one or more substrates in the boat being cross-slotted.

At least one 3D image may include at least part of a boat and the property may include a parameter indicative of an orientation of the boat relative to a horizontal plane.

At least one 3D image may include at least part of a boat and the property may include a parameter indicative of boat damage.

The substrate station may be a cassette for storing wafers. At least one 3D image may include at least part of a cassette for storing substrates and the property may include a parameter indicative of location of substrate(s) in the cassette.

At least one 3D image may include at least part of a cassette for storing substrates, the cassette comprising a door, and the property may include a parameter indicative of an open or closed status of the door.

At least one 3D image may include at least part of a cassette for storing substrates and the property may include a parameter indicative of one or more substrates in the cassette being cross-slotted.

According to a second aspect of the present invention there is provided a method of operating a substrate handling system comprising a substrate handling robot and a lidar imaging system comprising a lidar image acquisition module located on the substrate handling robot, the method being executable by a control module for controlling the lidar imaging system, the control module including a processor and a memory storing instructions that, when executed by the processor, cause the control module to perform the method comprising the steps of causing the lidar image acquisition module to acquire at least one 3D image of a substrate and/or a substrate station and determining one or more properties of the substrate and/or the substrate station, based on the at least one 3D image.

The control module may be or may or include a control module for controlling the substrate handling robot, and the instructions stored in the memory, when executed by the processor, may cause the control module to perform the method comprising the steps of controlling the substrate handling robot to adopt a first robot position such that the lidar image acquisition module has a first position relative to a substrate and/or substrate station, causing the lidar image acquisition module to acquire at least one first 3D image of the substrate and/or substrate station, controlling the substrate handling robot to adopt a second robot position such that the lidar image acquisition module has a second position relative to the same substrate and/or substrate station, causing the lidar image acquisition module to acquire at least one second 3D image of the substrate and/or substrate station, and determining one or more properties of the substrate and/or the substrate station based on the at least one first 3D image and the at least one second 3D image.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

Certain embodiments of the present invention will now be described, by way of example, with reference to the accompanying drawings, in which:

FIG. 1 is a schematic top view of an example of a furnace in which embodiments of the present invention may be comprised;

FIG. 2a is a schematic perspective view of a substrate handling robot which may be comprised in embodiments of the present invention;

FIG. 2b is a schematic perspective view of a substrate handling robot which may be comprised in embodiments of the present invention, which is supporting a wafer;

FIGS. 3a to 3g are schematic perspective views of a substrate handling robot supporting a lidar image acquisition module in various locations according to embodiments of the present invention;

FIG. 4 is a flow chart of a method according to embodiments of the present invention;

FIG. 5 is a flow chart of a modified version of the method illustrated in FIG. 4.

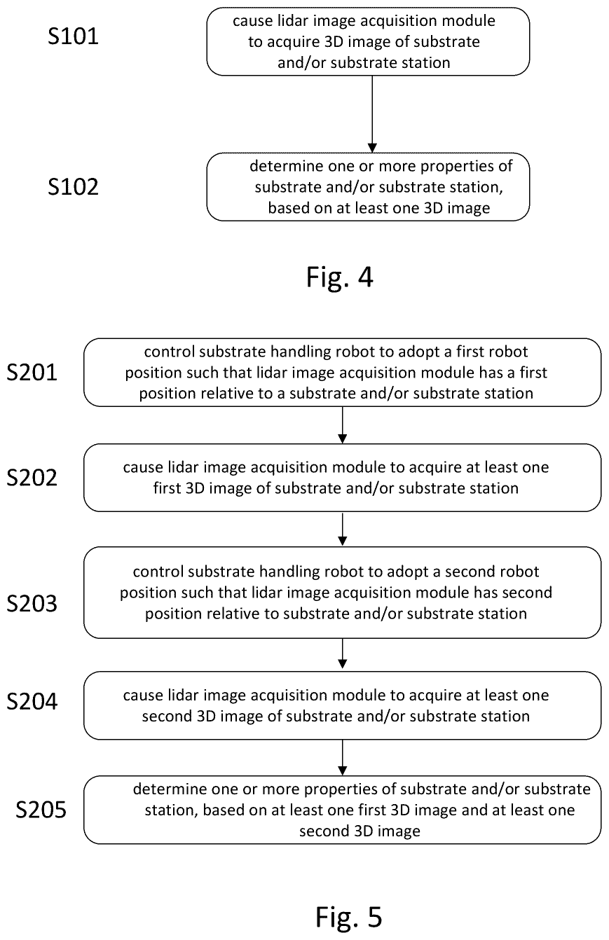

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

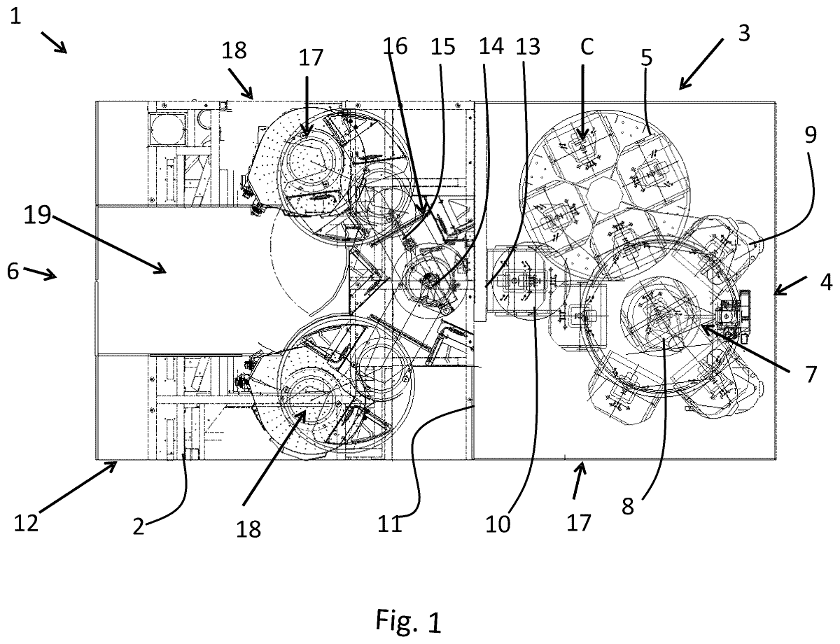

Referring to FIG. 1, a schematic top view of a substrate processing apparatus or furnace 1 in which a substrate handling system according to embodiments of the present invention may be comprised, is shown. The furnace 1 comprises a housing 2 with a front wall 4 and a back wall 6.

The furnace 1 may comprise a cassette module 3 with a storage device such as a cassette storage carousel 5 for storing a plurality of wafer cassettes C which wafer cassettes each accommodate a plurality of substrates. The cassette storage carousel 5 may comprise a number of platform stages for supporting cassettes. The platform stages may be connected to a central axis which is mounted rotatable around a vertical axis. Each platform stage is configured for accommodating a number of cassettes C. A drive assembly is operatively connected to the central axis for rotating the central axis with the number of platform stages around the vertical axis.

The cassette module 3 may have a cassette handler 7 having a cassette handler arm 8 configured to transfer cassettes C between the cassette storage carousel 5, a cassette in-out port 9 adjacent the front wall 4 of the housing 2 of the furnace 1, and/or a load port 10. The cassette handler 7 may comprise an elevating mechanism to reach to the cassettes at different height. Each platform stage for storing cassettes may have a cut-out therein, the cut-out being sized and shaped to allow the cassette handler arm 8 to pass vertically therethrough and to allow the platform stage to support a cassette C thereon.

An internal wall 11 separating the cassette module 3 from processing module 12 may be provided. The internal wall 11 may have a closable substrate access opening 13 adjacent the load port 10 which may be constructed and arranged to also open the cassette. The load port 10 may be provided with a cassette turntable to turn the cassette C and/or to press it against the closeable substrate access opening 13.

The processing module 12 may comprise a substrate handling robot 14 provided with a substrate handling arm 15 to transfer substrates from a cassette C positioned on the load port 10 through the closeable substrate access opening 13 to a substrate rack, or boat, and vice versa. The furnace may comprise a substrate handling chamber 16 in which the substrate handling robot 14 is accommodated.

The housing 2 may have a first and second side wall 17 extending over the full length of the furnace 1. Maintenance of the furnace 1 may be performed from the backside 6 or front side 4 of the furnace so that there may be no need for doors in the side walls 16.

With the construction of the sidewalls 17 without doors multiple furnaces 1 may be positioned side by side in a semiconductor fabrication plant. The sidewall of adjacent furnaces may thereby be positioned very close together, or are even against each other. Advantageously, the multiple furnaces may form a wall with the front side 4 of the furnaces 1 interfacing with a cassette transport device in a very clean environment of a so called “clean room” having very strict requirements for particles. The back side 6 of the furnace 1 may interface with a maintenance alley which may have less strict requirements for particles than the front side 4.

The furnace 1 may be provided with a first and a second reactor 18 for processing a plurality of substrates. Using two reactors may improve the productivity of the furnace 1. The substrate processing system in top view may be configured in a substantial U-shape. The first and second reactors 18 may be constructed and arranged in the legs. A maintenance area 19 may be constructed and arranged between the legs of the U-shape.

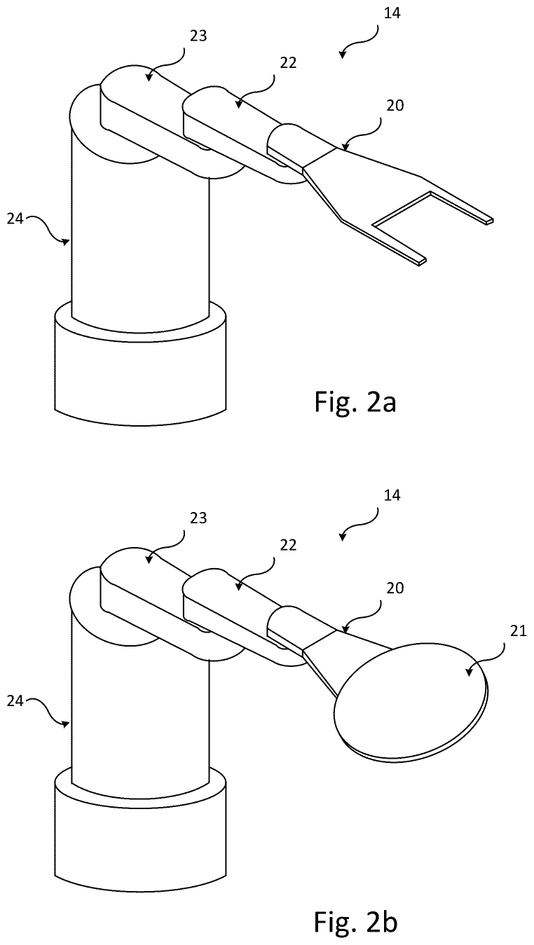

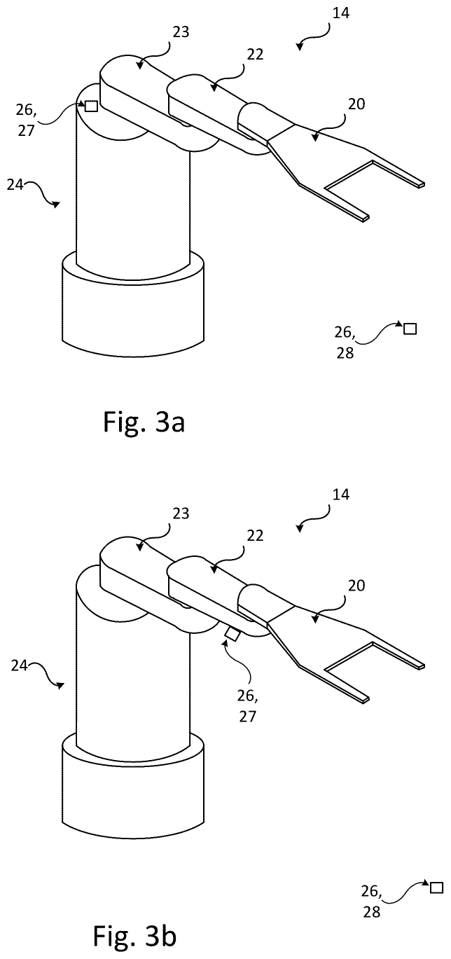

A substrate handling robot 14 according to embodiments of the present invention is shown in more detail in FIGS. 2a and 2b. The robot 14 includes an end effector 20, which is configured to pick up a wafer 21, support the wafer 21 during a wafer transfer step, and then deliver the wafer 21 to a target station. The target station may be for example a substrate rack or boat, a cassette, a susceptor, etc. In some embodiments, the end effector 20 may be a dual or multiple end effector which is capable of transporting more than one substrate at the same time.

The robot 14 also includes arms 22 and 23. The arm 22 has one end rotatably linked to the end effector 20, and another end rotatably linked to an end of the arm 23. The arm 23 has an opposite end rotatably linked to an elevator 24 which is configured to translate the arms 22, 23 and end effector 20 in a vertical direction. The elevator 24 may be configured to rotate about a vertical axis to facilitate rotation of the arms 22, 23 and end effector 20. The translation and/or rotation may be achieved by providing the elevator 24 as a support 30 which is supported in a base 31 such that the support 30 can be translated vertically relative to the base 31 and rotated relative to the base 31. It will be understood that although the example embodiment shown in FIG. 2 has two rotatably linked arms, a substrate handling robot 14 according to embodiments of the present invention may have three or more rotatably linked arms.

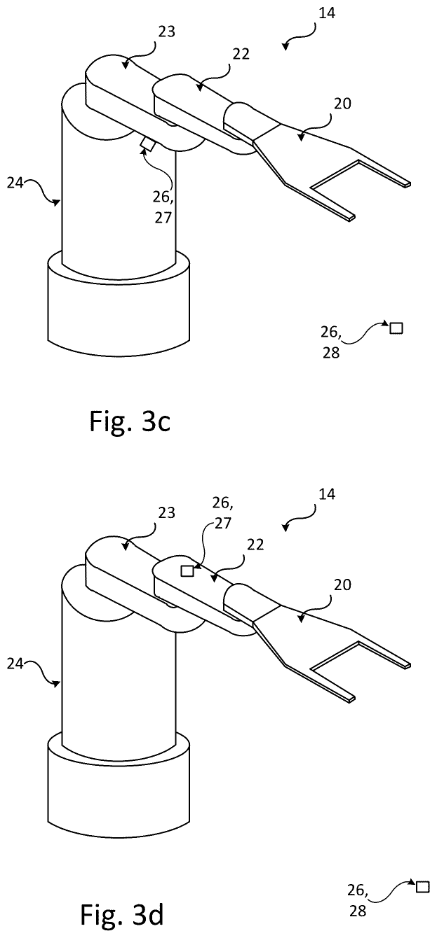

The substrate handling robot 14 is comprised in a substrate handling system 25. The substrate handling system 25 comprises the substrate handling robot 14 and a lidar imaging system 26. The lidar imaging system 26 comprises a lidar image acquisition module 27 disposed on the substrate handling robot 14. The lidar image acquisition module 27 may be disposed, for example, on the elevator 24 or on one of arms 22 and 23 or on the end effector 20. In embodiments wherein the substrate handling robot 14 comprises more than two rotatably linked arms, the lidar imaging system may be disposed on any of those arms. By “on the elevator” or “on the arm” it is meant that the lidar image acquisition module 27 may be disposed on any surface of the element referred to. By means of example, understanding that other locations of the lidar image acquisition module 27 on the substrate handling robot 14 are possible, referring to FIG. 3a, in an embodiment the lidar image acquisition module 27 may be located on an upper surface of the elevator 24. Referring to FIG. 3b, in an embodiment, the lidar image acquisition module 27 may be located on a lower surface of the arm 22. Referring to FIG. 3c, in an embodiment, the lidar image acquisition module 27 may be located on a lower surface of the arm 23. Referring to FIG. 3d, in an embodiment, the lidar image acquisition module 27 may be located on an upper surface of the arm 22. Referring to FIG. 3e, in an embodiment, the lidar image acquisition module 27 may be located on an upper surface of the arm 23. By locating the lidar image acquisition module 27 on the elevator 24, the vertical position of the lidar image acquisition module 27 can be changed by causing the elevator to move in the vertical direction. By locating the lidar image acquisition module 27 on an arm 22, 23, the vertical position of the lidar image acquisition module 27 can be changed by causing the elevator to move in the vertical direction and the position of the lidar image acquisition module 27 in the horizontal plane can be changed by rotating the arm 22, 23. Locating the lidar image acquisition module 27 on the arm 22 which is directly linked to the end effector may provide more control over the position of the lidar image acquisition module 27 in the horizontal plane as compared to locating the lidar image acquisition module 27 on the arm 23 which is directly linked to the elevator 24.

Referring to FIG. 3f, the lidar image acquisition module 27 may be located on an upper surface of the arm 22. This may provide more detailed imaging of a wafer held by the end effector 20 due to closer positioning to the end effector 20. Referring to FIG. 3g, the lidar image acquisition module 27 may be located on an upper surface of the arm 23. FIGS. 3f and 3g show the substrate handling system 25 in a retracted position, as compared to the extended position shown in FIGS. 3a to 3e.

The lidar image acquisition module 27 comprises one or more light sources, e.g. lasers, for scanning a field of view and one or more light detectors, e.g. photodetectors, photodiodes, CCDs or other light detectors, for detecting light emitted from the one or more light sources which has been scattered and/or reflected back by object(s) in the field of view. The light source(s) may be configured to emit continuous or pulsed light. The time between emission of the light and detection by the light detector is related to the distance between the lidar module 27 and an object by which the emitted light was scattered and/or reflected.

Scanning of the field of view may be achieved, for example, by changing the orientation of a mirror on which the light from the light source(s) is incident so as to deflect the transmission direction of the light. For example, by rotating a mirror around an axis in the vertical plane, a horizontal line scan can be made, and vice versa. By carrying out successive horizontal (or vertical) line scans at varying vertical (or horizontal) deflections, a field of view can be mapped in three dimensions. A single three dimensional image acquired by the lidar image acquisition module 27 includes depth information. This information is not present in a two-dimensional image.

The substrate handling system 25 may be configured to acquire at least one 3D image while the substrate handling robot 14 is in motion. For example, the substrate handling system 25 may include a robot control module configured to control motion of the substrate handling robot 14. The robot control module may be configured to control the substrate handling robot 14 to cause the substrate handling robot 14 to transfer a substrate from one substrate station to another substrate station and the robot control module may be configured to send a signal to the lidar imaging system 26 to cause the lidar imaging system 26 to acquire one or more 3D images while the substrate handling robot 14 is transferring a substrate from one substrate station to another substrate station.

The substrate handling system 25 may be configured to acquire at least one 3D image while the substrate handling robot 14 is stationary. For example, the robot control module may be configured to control the substrate handling robot 14 to be stationary and the robot control module may be configured to send a signal to the lidar imaging system 26 to cause the lidar imaging system 26 to acquire one or more 3D images while the substrate handling robot is stationary.

The substrate handling system 25 may be configured to acquire at least one 3D image of a substrate and/or a substrate station while the lidar image acquisition module 27 has a first position relative to the substrate and/or substrate station, to change the relative position of the lidar image acquisition module 27 relative to the substrate and/or substrate station by controlling the substrate handling robot 14 such that the lidar image acquisition module 27 has a second position relative to the substrate and/or substrate station different to the first position, and to acquire at least one 3D image while the lidar image acquisition module 27 has the second position relative to the substrate and/or substrate station. This can allow a series of images of an object to be acquired such that a more complete view of the object is provided. In some embodiments, the 3D images may be combined to form a combined image of the same substrate and/or substrate station, providing a more comprehensive view from multiple angles. This can help to detect, for example, damage which is only visible from one angle and which would be missed if only acquiring images from a different angle. It will be understood that more than two images may be acquired and combined.

In some embodiments, the substrate handling system 25 may be configured to acquire a first 3D image of a substrate and/or substrate station, to cause the elevator of the substrate handling robot 14 to move in the vertical direction, and to acquire a second 3D image of the substrate and/or substrate station. This can allow a series of 3D images of the same substrate and/or substrate station to be taken from different positions along the same vertical axis. In some embodiments, the substrate handling system may be configured to acquire a first 3D image of a substrate and/or substrate station, to cause the arm 22 and/or the arm 23 to change position, and to acquire a second 3D image of the substrate and/or substrate station. This can allow a series of 3D images to be taken from different positions in the same horizontal plane. In some embodiments, the substrate handling system 25 may be configured to acquire a first 3D image of a substrate and/or substrate station, to cause the elevator of the substrate handling robot 14 to move in the vertical direction, to cause the arm 22 and/or the arm 23 to change position, and to acquire a second 3D image of the substrate and/or substrate station. This can allow a series of 3D images to be taken from different horizontal and vertical positions. Thus a combined image of a substrate and/or substrate station can be built up by combining 3D images taken from different angles. One or more properties of the substrate and/or substrate station may be determined based on the combined 3D image using methods described herein in relation to non-combined 3D images.

For example, in some embodiments, the substrate station may be a boat and the substrate handling system 25 may be configured to acquire a series of 3D images of the boat, wherein for each 3D image the lidar image acquisition module 27 has a different position relative to the boat. This can provide a more comprehensive view of the boat as compared with a single 3D image, for example damage that may only be visible from one side of the boat may be identified. It will be understood that in embodiments described herein, if a 3D image is referred to, more than one 3D image may also be used.

In some embodiments, the lidar imaging system 26 may comprise a control module 28. The control module 28 may be configured to control the lidar image acquisition module 27, for example to cause the lidar image acquisition module 27 to carry out a scanning event. The control module 28 may be configured to provide parameters for the scanning event to the lidar image acquisition module 27, for example scan angle, scan duration, scan speed. The lidar image acquisition module 27 may be configured to provide lidar image data to the control module 28 or to one or more other control and/or processing modules of the furnace system 1 for further processing. The control module 28 for the lidar image acquisition module and the substrate transfer robot control module may be combined in a single control module for the substrate transfer system. It will be understood that a position of the control module 28 shown in the Figures does not necessarily denote a physical relative position of the control module 28 and the substrate handling robot 14. Herein, where a control module is referred to, such a control module may comprise a processor and a memory storing instructions which, when executed by the processor, cause operations to be carried out. For example, a control module for the lidar image acquisition module may store instructions in a memory which, when executed by the processor, cause the lidar image acquisition module to carry out one or more of the following operations: acquire a 3D image; send an acquired 3D image to another module; determine a property based on a 3D image; receive a 3D image; store a 3D image; etc. A control module for the substrate transfer robot may store instructions in a memory which, when executed by the processor, cause the substrate transfer robot to change its orientation, pose, and/or position, to pick up or place a substrate, to remain stationary, etc.

The control module 28 may include a processing module configured to receive and to process 3D image data received from the lidar acquisition module. The processing module 28 may be configured to determine one or more properties of the substrate and/or the substrate station based on the 3D image data. In some embodiments, the processing module 28 may be configured to compare the one or more properties with one or more reference values, reference data, or reference images. Determining one or more properties may comprise identifying a substrate or part thereof and/or substrate station or part thereof using computer vision methods such as object detection, object recognition, 3D reconstruction, 3D pose estimation, based on the at least one 3D image. Determining one or more properties may comprise generating a model, outline, profile, map, or other representation of the substrate and/or substrate station based on at least one 3D image.

In some embodiments, the control module 28 including a processing module may be configured to send data indicative of one or more properties of the substrate and/or substrate station to, for example, a central control module of the furnace system 1 and/or a peripheral control module or modules of the furnace system 1 for further evaluation, such as comparison with reference values, data, or images. The central control module may store the one or more properties in a memory, for example a database of wafers. In some embodiments, a control module of the furnace system, for example the control module 28 or central control module or peripheral control module (such as, for example, a reactor control module, a gas flow control module, etc.), may be configured to receive data indicative of one or more properties of the substrate and/or substrate station and to carry out one or more further actions based on the data.

Determining one or more properties of a substrate based on the 3D image may comprise comparing the 3D image with a reference image. The reference image may be an image acquired by the lidar image acquisition module 27 or an image received from an external source and stored in the control module 28. For example, a substrate may be imaged using the lidar image acquisition module 27 before and after processing in a reactor comprised in the furnace 1 and the image taken after processing may be compared with the image taken before processing to determine, for example, whether damage to the substrate has occurred.

The one or more properties of the substrate and/or the substrate station may include one or more properties of the substrate. At the time of image acquisition, in some embodiments the substrate may be located in a substrate station. In some embodiments, at the time of image acquisition, the substrate may be supported by the end effector of the substrate transfer robot 14. In some embodiments, at the time of image acquisition, the substrate may be simultaneously partially supported by a slot or other support in a substrate station and partially supported by the substrate transfer robot 14, for example if an image is acquired during a process of transferring a substrate to/from a substrate station.

In some embodiments, the lidar image acquisition module 27 may be configured to acquire a 3D image including (part of) the substrate or wafer and the lidar imaging system 26 may be configured to determine a warpage amount of the wafer based on the acquired 3D image. The warpage amount of a substrate or wafer may be provided to a user of the furnace 1, for example displayed on a display screen of the furnace or stored in a memory unit of the furnace. Determining a warpage amount of the wafer may comprise, for example, identifying the wafer (for example using computer vision techniques) and determining a warpage amount based on the identified wafer shape and a reference wafer profile. Other warpage determination methods may be used based on the 3D image of the wafer. The wafer may be located at a substrate station, for example in a boat or susceptor or cassette, or may be supported by an end effector, when the image is acquired.

In some embodiments, the lidar image acquisition module 27 may be configured to acquire a 3D image including (part of) the substrate or wafer and the lidar imaging system 26 may be configured to determine a thickness of the wafer based on the acquired 3D image. The thickness of a substrate or wafer may be provided to a user of the furnace 1, for example displayed on a display screen of the furnace or stored in a memory unit of the furnace. Determining a thickness of the wafer may comprise, for example, identifying the wafer (for example using computer vision techniques) and determining a thickness based on the identified wafer shape. The wafer may be located at a substrate station, for example in a boat or susceptor or cassette, or may be supported by an end effector, when the image is acquired.

In some embodiments, the lidar imaging system 26 may be configured to determine a location of a notch in the wafer based on the acquired 3D image. Notch location information can be useful for orienting the wafer correctly. The notch location information may be provided by the control module 28 to a control module for controlling the substrate handling robot. The control module for controlling the substrate handling robot may be configured to control the movement of the substrate handling robot based on the notch location information, for example to cause the substrate handling robot to rotate the substrate such that the notch has a particular orientation with respect to a substrate station or end effector. Determining a notch location may comprise, for example, identifying the wafer in the 3D image, extracting a wafer outline of the wafer, comparing the wafer outline with a reference wafer outline, and determining the notch location as a location at which the wafer outline deviates from the reference outline.

In some embodiments, the lidar imaging system 26 may be configured to determine a wafer identification code on the wafer based on the acquired 3D image. The wafer identification code may be provided to a control module of the furnace 1, for example to be stored/updated in a database of a control module of the furnace module associating wafer identification codes with wafer locations/positions. The wafer identification code may be, for example, a text and/or numerical code or a barcode. Determining the wafer identification code may comprise for example carrying out a text recognition method on the 3D image. The text recognition may be limited to a defined area of the image in which the wafer is known to be present, for example by identifying the wafer in the 3D image e.g. using a computer vision technique and restricting the text search to that area of the image which contains the wafer.

In some embodiments, the lidar imaging system 26 may be configured to determine a location of a center point of the wafer based on the acquired 3D image. By locating the wafer center, it can be checked whether the wafer is correctly positioned on the end effector. The substrate handling system 25 may be configured to cause the substrate handling robot 14 to adjust a position of a wafer based on the wafer center point determined from the 3D image. Determining the center point may comprise, for example, identifying the wafer in the 3D image, extracting a wafer outline, and using geometrical relations to determine the center position. Using a 3D image to determine the wafer center can allow a wafer center to be determined for a wafer which has a non-circular or non-oval shape, which may not be compatible with a standard wafer center finder using optical beam interruption methods calibrated to circular wafers.

In some embodiments, the lidar imaging system 26 may be configured to determine a damage status of the wafer based on the acquired 3D image, for example a classification as damaged or undamaged, or a parameter indicating a degree of damage. The substrate handling system 25 may be configured to cause the substrate handling robot 14 to transfer a wafer classified as damaged based on the acquired 3D image to a substrate storage station, such as a cassette, instead of transferring the wafer to a substrate processing station such as a boat. This can help to avoid processing wafers which are already damaged. Wafer damage may include breakage, for example sections of the wafer being missing. Determining wafer damage may comprise identifying the wafer in the 3D image, extracting a wafer outline, and comparing the wafer outline with an expected outline (e.g. a circular or oval shape) to determine position(s) at which the wafer deviates from the expected outline. Wafer damage may include for example scratches on the surface of the wafer. Determining wafer damage map comprise identifying the wafer in the 3D image and identifying any irregularities in the surface of the wafer which may be expected to otherwise be smooth.

In some embodiments, the lidar imaging system 26 may be configured to determine a degree of alignment of the wafer relative to a substrate holder based on the acquired 3D image. For example, the wafer may be placed in a ring holder and the ring holder may be placed in a boat and the degree of alignment of the wafer in the ring holder may be determined. The substrate handling system 25 may be configured to cause the substrate handling robot 14 to adjust a position of the wafer in the substrate holder depending on the determined degree of alignment. Determining a degree of alignment may comprise identifying the ring holder and the wafer in the 3D image, determining the center of both the ring holder and the wafer, and comparing the center positions.

In some embodiments, the substrate station may be a substrate holder. The 3D image may include at least part of a substrate holder and the one or more properties may include one or more properties of a substrate holder. The substrate holder may be a boat for supporting substrates during processing. The substrate holder may be a susceptor for supporting a substrate during processing. The substrate holder may be a cassette for storing substrates. Determining a property of a substrate holder based on the at least one 3D image may comprise identifying the substrate holder in the image. Identifying a substrate holder may comprise identifying one or more features in the image which are known to be comprised in the substrate holder. For example, a boat may comprise a number, e.g. 3, of boat rods extending in a vertical direction, a top and bottom plate to which the boat rods are attached at top and bottom ends, and a series of slots in the boat rods at regular intervals in the vertical direction for receiving wafers. Identifying the boat in the image may comprise identifying the boat rods e.g., by an image recognition or object detection process. Identifying the boat in the image may comprise identifying slots in the boat rods.

In some embodiments, the lidar imaging system 26 may be configured to determine a damage status of the boat based on the acquired 3D image, for example a damaged/undamaged classification, or a degree of damage classification, and/or a location of damage. If a damaged boat is used for supporting substrates during processing, damage can also occur to the substrates and/or the reactor. Therefore it is advantageous to identify boat damage as soon as possible. The substrate handling system 25 may be configured to send data indicative of boat damage status to a central control module of the furnace 1, which may be configured to stop a processing operation of the furnace 1 and/or to display a boat damage status message to a user depending on the boat damage status. Determining a damage status may comprise identifying a boat in the image, extracting an outline of the boat, and comparing the outline with a reference outline to identify any deviations. The reference outline may be a straight line, for example when determining whether damage has occurred in the boat rods. Determining a damage status may comprise identifying a boat in the image and identifying surface inconsistencies such as scratches or cracks in the boat.

In some embodiments, the lidar imaging system 26 may be configured to determine a position of the boat relative to the substrate handling robot based on the acquired 3D image. This can help to optimize movements of the substrate handling robot so as to accurately place wafers in the boat. As the acquired image is 3 dimensional, distances between the lidar image acquisition module and objects in the image can be accurately determined. The substrate handling system 25 may be configured to cause the substrate handling robot 14 to transfer a substrate to a position in the boat, the position being determined depending on the boat position acquired from the 3D image.

In some embodiments, the lidar imaging system 26 may be configured to determine a boat level measurement based on the acquired 3D image. The boat may include boat supports for substrates such as notches in the boat rods, projections attached to the boat rods, ring holder supports, ring holders, or other means for supporting a substrate during processing. If the boat is not level, placement/retrieval of substrates in such supports may be impacted as slippage may occur during pick up/placement if the end effector and the boat are not aligned in the same plane. The substrate handling system 25 may be configured to send data indicative of boat level status to a central control module of the furnace 1, which may be configured to stop a processing operation of the furnace 1 depending on the boat damage status and/or to display a boat level status message to a user of the furnace 1. Determining a boat level may comprise, for example, identifying a boat as described hereinbefore, identifying a feature which is expected to be horizontally levelled such as a top or bottom plate or one or more slots, generating a line or plane which is collinear or coplanar with the feature, and comparing the line or plane with a horizontal line or plane to determine any deviation.

In some embodiments, the lidar imaging system 26 may be configured to determine a boat part number based on the acquired 3D image, for example by taking a 3D image including a location on which the boat part number is provided, performing a text recognition process on the 3D image and identifying the part number. The substrate handling system 25 may be configured to send the boat part number to a central control module of the furnace 1, which may store and optionally display the boat part number to a user of the furnace 1.

In some embodiments, the lidar imaging system 26 may be configured to determine a position of one or more wafers or substrates in the boat based on the acquired 3D image. For example, the lidar imaging system 26 may acquire a 3D image of the boat, identify a boat in the image, identify a series of slots in the boat, and determine which slots or position in the boat contain a wafer. The substrate handling system 25 may be configured to cause the substrate handling robot 14 to unload wafers only from positions which contain a wafer and/or to load wafers only to positions which do not contain a wafer. This can save time in loading/unloading the boat.

In some embodiments, the lidar imaging system 26 may be configured to acquire a 3D image of the boat and, based on the 3D image, determine whether any wafers are cross-slotted in the boat, that is, whether any wafers are supported by slots or notches which are not in the same horizontal plane. The substrate handling system 25 may be configured to cause the substrate handling robot 14 to remove any cross-slotted wafers and to replace them in the boat in a correctly slotted position. Determining whether wafers are cross-slotted may comprise identifying a boat and slots as described hereinbefore, identifying a wafer in the boat, determining whether the wafer is level for example by generating a line or plane which is collinear (for example if the image is side-on to the plane of the wafer) or coplanar with the wafer, and comparing the line or plane with a reference horizontal line or plane. If the deviation between the wafer line or plane and the reference line or plane is greater than a predetermined value, the lidar imaging system 26 may classify the wafer as cross-slotted.

In some embodiments, the lidar imaging system 26 may be configured to, after loading of substrates into the boat has taken place but before processing of the wafers, acquire a 3D image of the boat and, based on the 3D image, determine a wafer depth in a boat support (e.g. slot or notch). The substrate handling system 25 may be configured to cause the substrate handling robot 14 to reposition any wafers which have an incorrect depth in the boat support. Determining a wafer depth may comprise identifying the boat and one or more slots or notches in the boat as described hereinbefore, identifying a center of the boat support, for example by using the position of the slots or notches as points on the circumference of a circle and determining the center of that circle, identifying a center of a wafer in the slot, for example as described hereinbefore, and comparing the positions of the center of the boat support and the center of the wafer. Determining a center of the boat support may be used in a process for correctly placing a wafer in the boat support. For example, the substrate handling system may be configured to acquire a 3D image including the boat support, identify the boat and one or more slots or notches in the boat as described hereinbefore, identify a center of the boat support, for example by using the position of the slots or notches as points on the circumference of a circle and determining the center of that circle, acquire an image of a wafer held on an end effector of the substrate handling robot, identify a center of the wafer, for example as described hereinbefore, and to position the wafer in the boat support such that the center of the wafer and the center of the boat support coincide.

In some embodiments, the lidar imaging system 26 may be configured to acquire a 3D image of a boat containing ring wafer supports and to determine a measure of ring sag based on the 3D image. Determining a measure of ring sag may comprise for example identifying a ring wafer support, determining or generating a surface profile of the ring wafer support, and comparing the surface profile with a horizontal plane to determine any deviation from the plane.

In some embodiments, the 3D image acquired may include at least part of a cassette and the lidar imaging system 26 may be configured to determine a property of the cassette based on the 3D image. The cassette may comprise an openable door through which substrates can be accessed. The cassette may comprise a series of slots or other supports for supporting wafers in the cassette.

In some embodiments, the lidar imaging system 26 may be configured to acquire a 3D image of a cassette and to determine a door open/closed status of the cassette based on the 3D image. The substrate handling system may be configured to cause the substrate handling robot 14 to pause a substrate transfer action based on the door open/closed status of the cassette. This can help to avoid collision of the end effector with the cassette door in case the cassette door is not open when a substrate transfer operation to/from the cassette is initiated. The substrate handling system 25 may be configured to provide the door open/closed status to a control module of the furnace 1, which may be configured to store and optionally display the door open/closed status to a user of the furnace 1. Determining the door open/closed status may comprise identifying the cassette in the image, for example using image recognition or object detection based on known properties of the cassette such as the shape of the cassette, identifying the door opening of the cassette, and determining whether the door is open or closed based on a distance measurement from the 3D image data. If the door is closed, the light emitted by the lidar image acquisition module will be scattered at a lesser distance from the lidar image acquisition module as compared to a case where the door is open, wherein the light is scattered by elements inside the cassette such as a back wall of the cassette, a substrate holder in the cassette, wafer(s) in the cassette, which are located at a greater distance from the lidar image acquisition module.

In some embodiments, the lidar imaging system 26 may be configured to acquire a 3D image of a cassette and to determine a status of a door seal of a door on the cassette. The substrate handling system may be configured to provide the door seal status to a control module of the furnace 1, which may be configured to store and optionally display the door seal status to a user of the furnace 1. The seal may be an inflatable seal which, when the door is open, should be retracted into a housing for the seal and should be flat and shiny. Deviation from this status can be indicative of damage to the seal. Determining a status of the door seal may comprise identifying the seal in one or more 3D images. Identifying the seal may comprise first identifying the cassette and then identifying the seal based on a region of the image containing the cassette. Determining a status of the door seal may comprise determining a measure of flatness of the seal based on distance measurements to various points on the seal. Determining a status of the door seal may comprise identifying surface inconsistencies in the seal, for example scratches.

In some embodiments, the lidar imaging system 26 may be configured to acquire a 3D image of a cassette and to determine a location of one or more wafers in one or more storage positions in the cassette. For example, the lidar imaging system 26 may acquire a 3D image of the cassette, identify a cassette in the image, identify a series of slots in the cassette, and determine which slots or position in the cassette contain a wafer. The substrate handling system 25 may be configured to cause the substrate handling robot 14 to unload substrates only from those locations in the cassette which contain a substrate as determined from the 3D image. This can help to save time in unloading the cassette by avoiding causing the substrate handling robot 14 to attempt to unload a substrate from a location in the cassette which does not contain a substrate. The substrate handling system may be configured to cause the substrate handling robot 14 to place substrates only in those locations in the cassette which do not currently contain a substrate as determined from the 3D image. This can help to avoid damaging substrates when transferring substrates to the cassette by avoiding substrates being placed directly on top of one another.

In some embodiments the lidar imaging system 26 may be configured to acquire a 3D image of the cassette and to determine a position of a substrate in a cassette storage slot, for example how far into the storage slot the wafer is positioned. Determining a wafer depth or other measure of wafer position may comprise identifying the cassette and one or more slots or other storage locations in the cassette as described hereinbefore, identifying a center of the cassette slot or support, for example by using the position of the slots or supports as points on the circumference of a circle and determining the center of that circle, identifying a center of a wafer in the slot, and comparing the positions of the center of the cassette support and the center of the wafer.

The substrate handling system 25 may be configured to cause the substrate handling robot 14 to change a position of a substrate in a cassette slot based on the substrate position or relative position with respect to the cassette support as determined from the 3D image. This can avoid damage to substrates in the cassette which may be caused by closing the door of the cassette while substrates are not fully inserted into slots in the cassette and may collide with the door.

In some embodiments, the lidar imaging system 26 may be configured to acquire a 3D image of the cassette and, based on the 3D image, determine whether any wafers are cross-slotted in the cassette, that is, whether any wafers are supported by slots or notches which are not in the same horizontal plane. Determining whether wafers are cross-slotted may comprise identifying a cassette and slots or wafer supports as described hereinbefore, identifying a wafer in the cassette, determining whether the wafer is level for example by generating a line or plane which is collinear (for example if the image is side-on to the plane of the wafer) or coplanar with the wafer, and comparing the line or plane with a reference horizontal line or plane. If the deviation between the wafer line or plane and the reference line or plane is greater than a predetermined value, the lidar imaging system 26 may classify the wafer as cross-slotted. The substrate handling system 25 may be configured to cause the substrate handling robot 14 to remove any cross-slotted wafers and to replace them in the cassette in a correctly slotted position.

In some embodiments, the lidar imaging system 26 may be configured to acquire a 3D image of the cassette and, based on the 3D image, determine a wafer size of a wafer in the cassette. In some embodiments the cassette may contain wafers having different sizes, e.g. one or more 200 mm wafers and one or more 300 mm wafers. It is important to identify which wafer has which size so that the wafers can be processed appropriately. For example, attempting to place a 300 mm wafer in a substrate holder designed for a 200 mm wafer would result in damage to the wafer. Determining a wafer size may comprise identifying a wafer in the 3D image, acquiring an outline of the wafer or identifying one or more points on the circumference of the wafer, and determining the size of the wafer based on the identified points. For example, if the image is taken in a side-on position in which the plane of the wafer is generally not visible, determining the size of the wafer may comprise identifying the two extremes of the wafer and determining their separation as the diameter of the wafer.

It will be understood that determining a property based on one or more 3D images may comprise determining a property directly from one or more 3D images, and may additionally or alternatively comprise determining a property based on one or more post-processed 3D images, for example image(s) which have been filtered, cropped, rotated, combined with one or more other 3D images acquired by the lidar image acquisition module 27, etc.

In some embodiments, the lidar imaging system 26 may comprise more than one lidar image acquisition module 27, both lidar image acquisition modules being located on the substrate handling robot 14, not necessarily on the same element, e.g. arm or elevator, of the substrate handling robot 14.

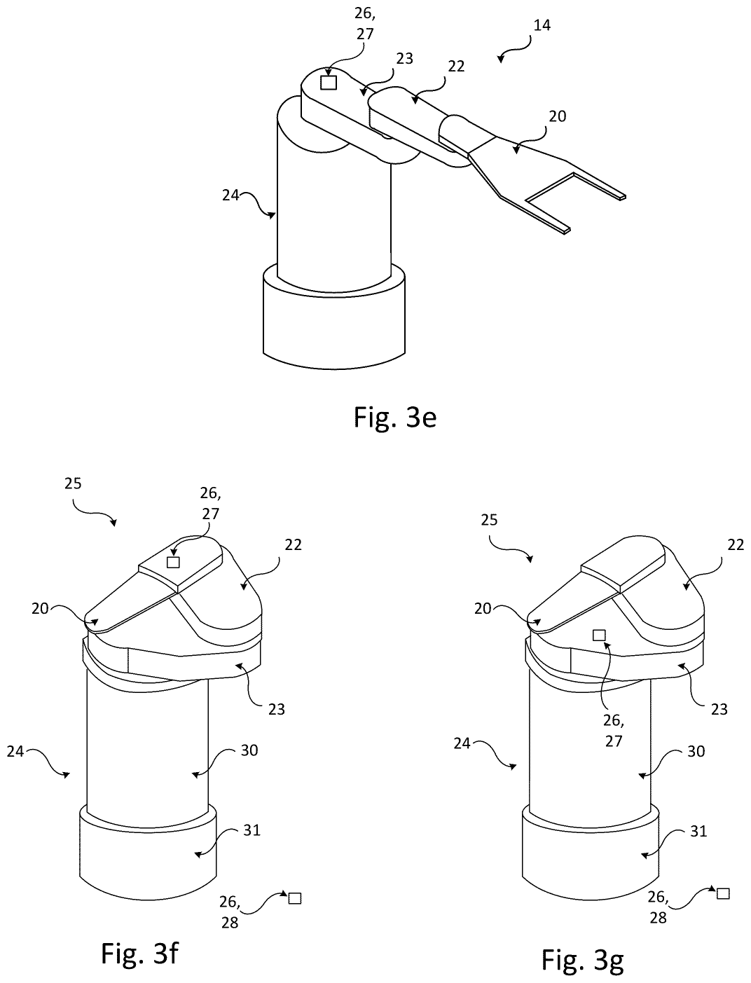

Referring to FIG. 4, a method according to embodiments of the present invention is presented. The method is a method of operating the substrate handling system 25 which comprises the substrate handling robot 14 and the lidar imaging system comprising the lidar image acquisition module located on the substrate handling robot 14. The method is executable by a control module for controlling the lidar imaging system. The control module includes a processor and a memory storing instructions that, when executed by the processor, cause the control module to perform the method comprising the following steps. In step S101, the lidar image acquisition module is caused to acquire at least one 3D image of a substrate and/or a substrate station. In step S102, one or more properties of the substrate and/or the substrate station are determined, based on the at least one 3D image.

In some embodiments, the control module may be or may include a control module for controlling the substrate handling robot. The control module may include a processor and a memory storing instructions that, when executed by the processor, cause the control module to perform the method comprising the following steps. In step S201, the substrate handling robot is controlled to adopt a first robot position such that the lidar image acquisition module has a first position relative to a substrate and/or substrate station. In step S202, the lidar image acquisition module is caused to acquire at least one first 3D image. In step S203, the substrate handling robot is controlled to adopt a second robot position such that the lidar image acquisition module has a second position relative to the same substrate and/or substrate station. In step S204, the lidar image acquisition module is caused to acquire at least one second 3D image. In step S205, one or more properties of the substrate and/or the substrate station are determined based on the at least one first 3D image and the at least one second 3D image.

Step S205 may be modified to include combining the at least one first 3D image and the at least one second 3D image to form a combined 3D image, followed by determining one or more properties of the substrate and/or the substrate station based on the combined 3D image.

Although illustrative embodiments of the present invention have been described above, in part with reference to the accompanying drawings, it is to be understood that the invention is not limited to these embodiments. Variations to the disclosed embodiments can be understood and effected by those skilled in the art in practicing the claimed invention, from a study of the drawings, the disclosure, and the appended claims.

Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, it is noted that particular features, structures, or characteristics of one or more embodiments may be combined in any suitable manner to form new, not explicitly described embodiments. The subject matter of the present disclosure includes all novel and nonobvious combinations and subcombinations of the various processes, systems, and configurations, and other features, functions, acts, and/or properties disclosed herein, as well as any and all equivalents thereof.

1. A substrate handling system comprising:
a substrate handling robot for transferring a substrate among a plurality of substrate stations; and
a lidar imaging system comprising a lidar image acquisition module located on the substrate handling robot, the lidar imaging system being configured to acquire at least one 3D image of a substrate and/or a substrate station, and to determine one or more properties of the substrate and/or the substrate station, based on the at least one 3D image.

2. The substrate handling system according to claim 1, wherein the lidar imaging system is configured to acquire at least one 3D image while the substrate handling robot is stationary.

3. The substrate handling system according to claim 1, wherein the lidar imaging system is configured to acquire at least one 3D image while the substrate handling robot is in motion.

4. The substrate handling system according to claim 1, wherein the lidar imaging system is configured to acquire a first 3D image of the substrate and/or substrate station from a first relative position and a second 3D image of the same substrate and/or substrate station from a second relative position different to the first relative position, and to determine one or more properties of the same substrate and/or substrate station based on the first and second 3D images.

5. The substrate handling system according to claim 4, wherein the lidar imaging system is configured to combine at least the first 3D image and the second 3D image of the same substrate and/or substrate station to create a combined image and to determine one or more properties of the substrate and/or substrate station based on the combined image.

6. The substrate handling system according to claim 1, comprising a substrate handling robot control module configured to receive at least one property determined based on at least one 3D image from the lidar imaging system, and to adapt a behavior of the substrate handling robot based on the at least one property.

7. The substrate handling system according to claim 6, wherein at least one 3D image includes at least part of a substrate and the at least one property includes a warpage of the substrate.

8. The substrate handling system according to claim 6, wherein at least one 3D image includes at least part of a substrate and the at least one property includes a parameter indicative of substrate damage.

9. The substrate handling system according to claim 6, wherein at least one 3D image includes at least part of a substrate and the at least one property includes a substrate identification code.

10. The substrate handling system according to claim 6, wherein at least one 3D image includes at least part of a substrate and the at least one property includes a position of a center of the substrate.

11. The substrate handling system according to claim 6, wherein at least one 3D image includes at least part of a boat and the at least one property includes a parameter indicative of location of substrate(s) in the boat.

12. The substrate handling system according to claim 6, wherein at least one 3D image includes at least part of a boat and the at least one property includes a parameter indicative of one or more substrates in the boat being cross-slotted.

13. The substrate handling system according to claim 6, wherein at least one 3D image includes at least part of a boat and the at least one property includes a parameter indicative of an orientation of the boat relative to a horizontal plane.

14. The substrate handling system according to claim 6, wherein at least one 3D image includes at least part of a boat and the at least one property includes a parameter indicative of boat damage.

15. The substrate handling system according to claim 6, wherein at least one 3D image includes at least part of a cassette for storing substrates and the at least one property includes a parameter indicative of location of substrate(s) in the cassette.

16. The substrate handling system according to claim 6, wherein at least one 3D image includes at least part of a cassette for storing substrates, the cassette comprising a door, and the at least one property includes a parameter indicative of an open or closed status of the door.

17. The substrate handling system according to claim 6, wherein at least one 3D image includes at least part of a cassette for storing substrates and the at least one property includes a parameter indicative of one or more substrates in the cassette being cross-slotted.

18. A method of operating a substrate handling system comprising a substrate handling robot and a lidar imaging system comprising a lidar image acquisition module located on the substrate handling robot, the method being executable by a control module for controlling the lidar imaging system, the control module including a processor and a memory storing instructions that, when executed by the processor, cause the control module to perform the method comprising the steps of:
causing the lidar image acquisition module to acquire at least one 3D image of a substrate and/or a substrate station; and
determining one or more properties of the substrate and/or the substrate station, based on the at least one 3D image.

19. The method according to claim 18, wherein the control module further includes controlling the substrate handling robot, wherein the instructions stored in the memory, when executed by the processor, cause the control module to perform the method comprising the steps of controlling the substrate handling robot to adopt a first robot position such that the lidar image acquisition module has a first position relative to a substrate and/or substrate station, causing the lidar image acquisition module to acquire at least one first 3D image, controlling the substrate handling robot to adopt a second robot position such that the lidar image acquisition module has a second position relative to the same substrate and/or substrate station, causing the lidar image acquisition module to acquire at least one second 3D image, and determining one or more properties of the substrate and/or the substrate station based on the at least one first 3D image and the at least one second 3D image.
